(19) United States
(12) Patent Application Publication
(10) Pub. No.: US 2024/0407175 A1
(43) Pub. Date: Dec. 5, 2024

(54) FERROELECTRIC TEMPERATURE SENSOR

(71) Applicant: TEXAS INSTRUMENTS INCORPORATED, Dallas, TX (US)

(72) Inventors: Scott R. SUMMERFELT, Garland, TX (US); Michael BALL, Richardson, TX (US); John RODRIGUEZ, Dallas, TX (US); Nagesh SURENDRANATH, Frisco, TX (US); Antoine Lourdes Praveen AROUL, Plano, TX (US); Eduardo BARTOLOME, Dallas, TX (US)

(21) Appl. No.: 18/326,939

(22) Filed: May 31, 2023

(51) Int. Cl. H10B 53/40; G11C 11/22; H10B 53/30

(52) U.S. Cl. CPC H10B 53/40; G11C 11/221; G11C 11/2259; H10B 53/30

(57) ABSTRACT

An apparatus includes: groups of ferroelectric memory bit cells; and memory interface circuitry having processing outputs and memory access terminals. The memory access terminals are coupled to the groups of ferroelectric memory bit cells. The memory interface circuitry is configured to: provide control signals via the memory access terminals to perform read operations on the groups of ferroelectric memory bit cells; receive first signals from the groups of ferroelectric memory bit cells via the memory access terminals from the read operations; and for each group of the groups of ferroelectric memory bit cells, provide second signals representing relationships between the first signals received from the group of ferroelectric memory bit cells and a respective reference voltage of the reference voltages at the processing outputs, the reference voltages representing different temperatures.

### BACKGROUND

A ferroelectric capacitor can include a ferroelectric material to store charge. In memory applications, a ferroelectric capacitor can form a memory cell, and the charge of the ferroelectric capacitor can represent a stored state/value of the memory cell. To perform a read operation to determine the current state of the memory cell, the amount of charge needed to flip the current state of the memory cell can be measured. A read operation may destroy the memory cell state, and can be followed by a corresponding write operation in order to restore the most recent memory cell state. Also, ferroelectric capacitor can undergo depolarization, which can also change the stored state of the memory cell. The degree of depolarization can vary with various factors, such as the amount of time elapsed from the most recent write operation, and the temperature of the ferroelectric capacitor.

### SUMMARY

In an example, an apparatus includes: groups of ferroelectric memory bit cells; and memory interface circuitry having processing outputs and memory access terminals. The memory access terminals are coupled to the groups of ferroelectric memory bit cells. The memory interface circuitry is configured to: provide control signals via the memory access terminals to perform read operations on the groups of ferroelectric memory bit cells; receive first signals from the groups of ferroelectric memory bit cells via the memory access terminals from the read operations; and for each group of the groups of ferroelectric memory bit cells, provide second signals representing relationships between the first signals received from the group of ferroelectric memory bit cells and a respective reference voltage of reference voltages at the processing outputs, the reference voltages representing different temperatures.

In another example, an apparatus includes a processing circuit having a processing output. The processing circuit is configured to: receive temperature sense signals from ferroelectric memory bit cells; detect a historical temperature excursion event based on the temperature sense signals; and provide an indication of the historical temperature excursion event at the processing output.

In another example, a method includes: providing, by a sensor, control signals to perform read operations on groups of ferroelectric memory bit cells; receiving, by the sensor, first signals from the groups of ferroelectric memory bit cells responsive to the read operations; and for each group of the groups of ferroelectric memory bit cells, providing, by the sensor, second signals representing relationships between the first signals received from the group of ferroelectric memory bit cells and a respective reference voltage of reference voltages, the reference voltages representing different temperatures.

In another example, a method includes: receiving, by a processor, temperature sense signals from ferroelectric memory bit cells; detecting, by the processor, a historical temperature excursion event based on the temperature sense signals; and outputting, by the processor, an indication of the historical temperature excursion event.

### BRIEF DESCRIPTION OF THE DRAWINGS

FIG. 1 is a graph representing temperature as a function of time.

FIG. 2A is a diagram illustrating an example device and ferroelectric temperature sensor subject to temperature excursion.

FIG. 2B is a diagram illustrating the example device and ferroelectric temperature sensor of FIG. 2A and example sensor data.

FIG. 3 is a diagram illustrating an example system.

FIG. 4 is a diagram illustrating an example ferroelectric hysteresis loop.

FIG. 5 is a graph representing normalized margin/polarization of a ferroelectric capacitor as a function of temperature.

FIG. 6 is a schematic diagram illustrating an example ferroelectric random-access memory (FRAM) circuit.

FIG. 7 include diagrams illustrating example write and subsequent read operations of FRAM.

FIG. 8 include diagrams illustrating example charge and voltage states of a ferroelectric capacitor during read operations of FRAM.

FIG. 9 is a diagram illustrating example components of a ferroelectric temperature sensor.

FIG. 10 is a diagram illustrating an example processing circuit.

FIG. 11 is a diagram illustrating another example system.

FIG. 12 is a flowchart illustrating an example method for a ferroelectric temperature sensor.

FIG. 13 is a flowchart illustrating an example method for detecting a historical temperature excursion event.

FIG. 14 is a cross-sectional view illustrating example integrated circuit (IC) that includes a ferroelectric temperature sensor.

### DETAILED DESCRIPTION

The same reference numbers or other reference designators are used in the drawings to designate the same or similar features. Such features may be the same or similar either by function and/or structure.

Described herein are temperature sensors and/or temperature excursion sensors based on ferroelectric capacitors and related ferroelectric memory bit cells. The ability of ferroelectric capacitors, used by such ferroelectric temperature sensors, to hold charge is affected by temperature. Above a threshold temperature or above a range of temperatures for an extended period of time, ferroelectric capacitors experience depolarization. Such depolarization results in the stored charge on a ferroelectric capacitor being changed (e.g., increased or reduced). If the charge stored by a ferroelectric capacitor is changed by more than a threshold, a determination can be made that the ferroelectric memory bit cell including that ferroelectric capacitor has failed, and the threshold can reflect a particular temperature.

In some examples, a ferroelectric temperature sensor includes groups of ferroelectric memory bit cells. Each group of ferroelectric memory bit cells can receive write operations to store charge. Subsequent read operations can then be performed on the groups of ferroelectric memory bit cells is performed to determine which, if any, of the groups of ferroelectric memory bit cells has failed (i.e., the bits obtained from the read operation should equal the bits of the previous write operation). In some examples, failure of one or more of the groups of ferroelectric memory bit cells is interpreted as a temperature excursion event, a specific temperature, a temperature range over time, or another temperature indicator. Lack of failure of some or all groups of ferroelectric memory bit cells may be interpreted as lack of a temperature excursion event, lack of a specific temperature, a lack of a temperature range over time, or lack of another temperature indicator. The threshold at which the failure rate reaches a particular percentage (e.g., 50%) can also be used to determine the temperature (or temperature range) the groups of ferroelectric memory bit cells are exposed to prior to the read operations. One of the benefits of ferroelectric temperature sensors is that they can detect a temperature excursion without an ongoing power supply. Also, in some examples, the ferroelectric temperature sensors do not need to be connected to a dedicated power source (e.g., battery), and the read/write operations can be powered wirelessly by a remote power source. Such arrangements allow the ferroelectric temperature sensors to be deployed in various applications, such as packaging of temperature sensitive goods (e.g., medical supply, perishable food, electronics, etc.), where detection of temperature excursion events can be useful (e.g., to determine whether the medical supply has been sterilized, whether the goods have been subject to high temperature that may damage the goods, etc.).

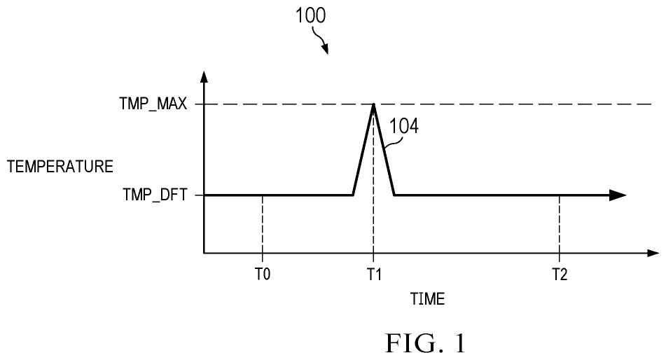

FIG. 1 is a graph 100 representing temperature as a function of time. As shown, the temperature stays at a default temperature (TMP_DFT) except during a temperature excursion 104. TMP_DFT may be room temperature or another stable temperature. Thus, at time T0, the temperature is at TMP_DFT. At time T1, the temperature is at a maximum temperature (TMP_MAX). At time T2, the temperature is at a maximum temperature (TMP_MAX). At time T3, the temperature is at TMP_DFT again. In different examples, the amplitude and/or duration of the temperature excursion 104 may vary.

In some examples, write operations to a ferroelectric temperature sensor are performed at time TO. At time T1, a temperature excursion occurs. While the plot shows this as a short event it can vary from minutes to hours to days. At time T2, read operations to a ferroelectric temperature sensor are performed. The read operations provide temperature indicators that are used to determine TMP_MAX and/or the occurrence of the temperature excursion 104. In some examples, ferroelectric temperature sensors may be combined with other sensors having charge storage cells, such as electrically erasable programmable read-only memory (EEPROM) or a phase change resistor. These sensors detect temperature excursion as well as a time element. Such combined sensors may even be able to detect the duration of a temperature excursion. The complexity of ferroelectric temperature sensors may vary depending on the application.

In one example, ferroelectric temperature sensors are used as autoclave sensors. In this first example, each ferroelectric temperature sensor may be configured to detect a temperature or temperature excursion related to autoclave sterilization. Without limitation, each such ferroelectric temperature sensor may be attached to an instrument or to a container to be inserted in the autoclave. As another example, ferroelectric temperature sensors are used as solder reflow sensors. In this second example, each ferroelectric temperature sensor may be configured to detect a temperature or temperature excursion related to a solder melting point. Without limitation, each such ferroelectric temperature sensor may be attached to a device or circuit subject to a solder reflow process. Other use cases are possible. The durability, cost, and design flexibility of ferroelectric temperature sensors is an advantage over other temperature sensor options. To reduce its footprint, ferroelectric temperature sensors can be designed without a power supply. In one example, the power needed to operate a ferroelectric temperature sensor may be received from a radio-frequency (RF) signal used to power and query the ferroelectric temperature sensor.

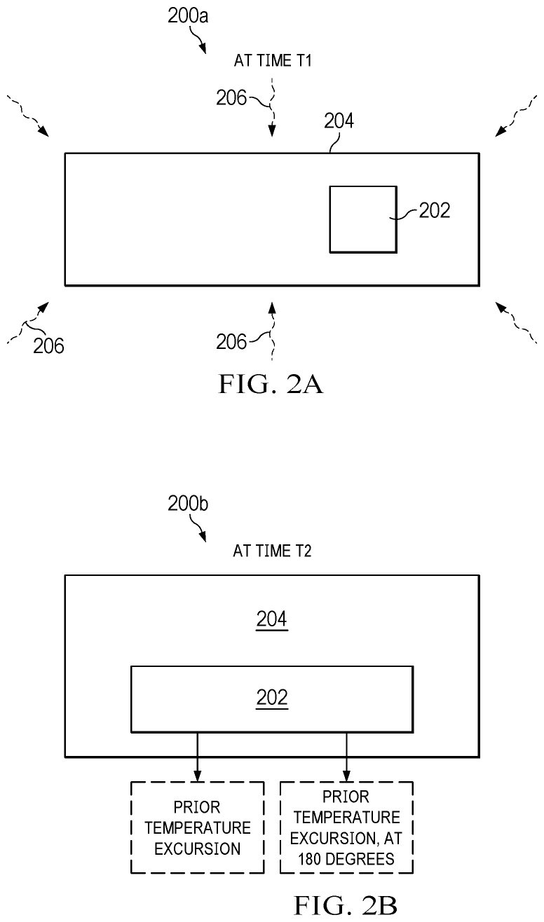

FIG. 2A is a diagram 200a illustrating an example device 204 and a ferroelectric temperature sensor 202 subject to temperature excursion 206. In different examples, the device 204 may be a medical instrument, a printed circuit board (PCB), a container, or other device subject to a planned or unplanned temperature excursion 206 at time T1 (see FIG. 1). The ferroelectric temperature sensor 202 includes an integrated circuit with ferroelectric capacitors. In some examples, the ferroelectric temperature sensor 202 is a sensor tag or portable unit attached to the device 204 using adhesive, screws, or another attachment mechanism. In different examples, the ferroelectric temperature sensor 202 may be disposable after one use or may be re-useable. It may also be possible to reconfigure the ferroelectric temperature sensor 202 for use with different temperature ranges.

FIG. 2B is a diagram 200b illustrating the example device 204 and ferroelectric temperature sensor 202 of FIG. 2A as well as example sensor data. In the example of FIG. 2B, the ferroelectric temperature sensor 202 provides temperature indications at time T2 (see FIG. 1) such as an indication of prior temperature excursion and/or an indication of prior temperature excursion at a particular temperature (e.g., 180° C.). In various examples, the ferroelectric temperature sensor 202 provides such temperature indications responsive to a query, a schedule, and/or other output trigger.

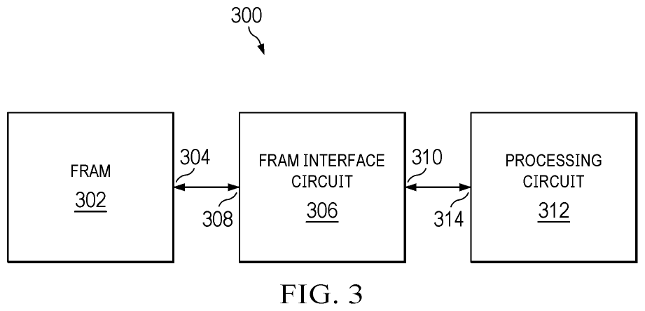

FIG. 3 is a diagram illustrating an example system 300. As shown, the system 300 includes ferroelectric random-access memory (FRAM) circuitry 302, a FRAM interface circuit 306, and a processing circuit 312. The FRAM circuitry 302 has a communication interface 304. The FRAM interface circuit 306 has a first communication interface 308 and a second communication interface 310. In some examples, the first communication interface 308 includes memory access terminals, and the second communication interface 310 includes processing outputs. The processing circuit 312 has a communication interface 314. In different examples, each of the communication interface 304 of the FRAM circuitry 302, the first communication interface 308 and the second communication interface 310 of the FRAM interface circuit 306, and/or the communication interface 314 of the processing circuit 312 may include one or more terminals. Herein, the second communication interface 310 is sometimes described as having processing outputs. In some examples, a ferroelectric temperature sensor includes all components of the system 300. In other examples, a ferroelectric temperature sensor includes only the FRAM circuitry 302. In other examples, a ferroelectric temperature sensor includes the FRAM circuitry 302 and the FRAM interface circuit 306. In some examples, the FRAM circuitry 302 can be dedicated for temperature excursion sensing and does not have to be dedicated for memory operation. Alternatively, the FRAM circuitry 302 can used for both temperature excursion sensing as well as normal memory operations. In this situation, the ferroelectric capacitors for temperature sensing can be the same or different than those used for memory operations. In some examples, the processing circuit 312 is separate from and in communication with the ferroelectric temperature sensor via a communication channel. In some examples, the communication channel is a wireless communication channel.

In the example of FIG. 3, the processing circuit 312 queries the FRAM circuitry 302 for temperature indicators via the FRAM interface circuit 306. The requested temperature indicators are provided to the processing circuit 312 via the FRAM interface circuit 306 and are interpreted by the processing circuit 312. The result of the query and interpretation by the processing circuit 312 may be a temperature, a temperature excursion flag or event, an alert, or other result. After the query, the processing circuit 312 may reset the FRAM circuitry 302 via the FRAM interface circuit 306. The reset may store the same bits as before or may store other bits. As another option, the reset may update the detectable temperature range or temperature excursion threshold of the FRAM circuitry 302.

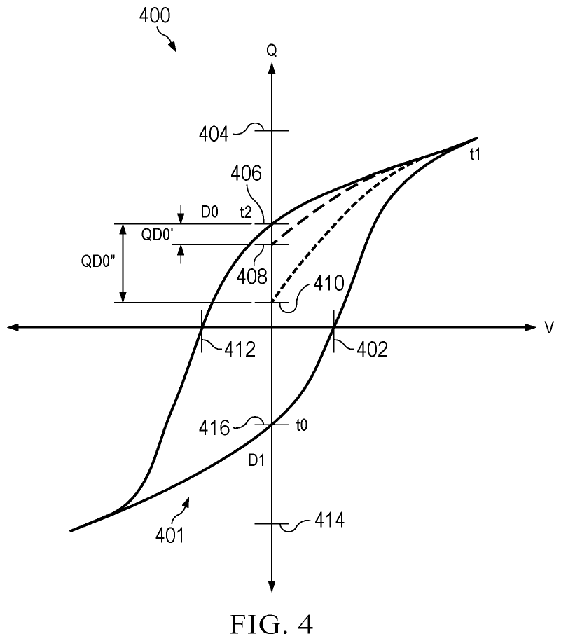

FIG. 4 is a diagram 400 illustrating an example ferroelectric hysteresis loop 401. In diagram 400, the ferroelectric hysteresis loop 401 can present a pattern of charge stored in a ferroelectric capacitor as a function of voltage. The ferroelectric hysteresis loop 401 shows the dependence of electric polarization of ferroelectric materials on applied electric field as well as previous polarization. At time to, the ferroelectric material is initially at a negative polarization 416 due to a previous application and removal of a negative electric field beyond negative threshold 412. At time t1, the ferroelectric material is at a maximum positive polarization 404 due to application of a positive electric field beyond positive threshold 402. This positive polarization can be considered to be a read pulse. At time t2, the ferroelectric material is at a positive polarization 406 due to application and removal of the positive electric field beyond positive threshold 402. During a subsequent application of a negative electric field beyond the negative threshold 412, the ferroelectric material would be at a maximum negative polarization 414. Once the negative electric field is removed, the ferroelectric material would return to the negative polarization 416. The process of ferroelectric material polarization can be repeated as desired by application of a positive or negative electric field.

To use ferroelectric material as memory, its polarization is set via a write operation and then the polarization is later read via a read operation. Because the read operation removes the existing polarization, a subsequent write operation may be performed to restore the original polarization. In diagram 400, first and second reduced positive polarizations 408 and 410 are shown. The first reduced positive polarization 408 results from the ferroelectric material being at the positive polarization 406 and then being subject to a first partial depolarization. The second reduced positive polarization 410 results from the ferroelectric material being at the positive polarization 406 and then being subject to a second partial depolarization, where the second partial depolarization is greater than the first partial depolarization.

Diagram 400 also associates the positive polarization 406 with a non-switched ferroelectric capacitor (D0) and associates the negative polarization 416 with a switched ferroelectric capacitor (D1). During FRAM operations, D0 and D1 will have opposite polarities. The difference between the positive polarization 406 and the first reduced positive polarization 408 is a first depolarization amount QD0′. The difference between the positive polarization 406 and the second reduced positive polarization 410 is a second depolarization amount QD0″. Ferroelectric capacitors may depolarize due to two mechanisms: retention; and thermal depolarization. Retention depolarization increases with longer hold times and higher temperatures. Thermal depolarization does not depend on time but just the maximum temperature. For switched ferroelectric capacitors, depolarization results is a decrease in charge. For non-switched ferroelectric capacitors, depolarization results in an increase in charge. In some examples, the occurrence and/or amount of depolarization related to D0 or D1 is detectable and can be used to estimate a temperature excursion.

The ferroelectric effect described in FIG. 4 is the basis for FRAM. The two relatively stable positions at 0V not only defines a ferroelectric material but also is the means of creating a non-volatile memory. To determine the polarity of a ferroelectric capacitor, different voltages are applied and depending on its previous polarization a different amount of polarization is measured. A temperature excursion reduces the polarization moving the intrinsic polarization from the outer loop to an inner loop. This happens for both the upper and lower hysteresis loop. The voltages at the first and second reduced positive polarizations 408 and 410 are inner loop points that might occur due to a temperature excursion after being originally written at the positive polarization 406. In one example, after applying a positive voltage pulse, a delta charge (QD0′) may occur due to a temperature excursion, causing the voltage on a ferroelectric capacitor to change from the positive polarization 406 to the first reduced positive polarization 408. With a larger temperature excursion, a larger delta charge (QD0″) may occur, causing the voltage on a ferroelectric capacitor to change from the positive polarization 406 to the second reduced positive polarization 410.

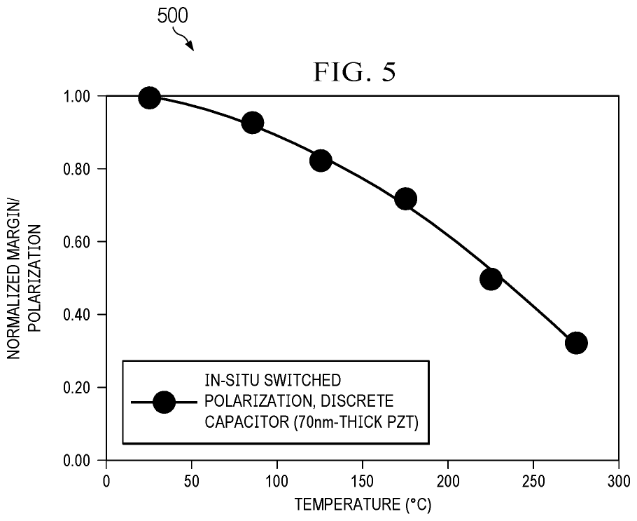

FIG. 5 is a graph 500 representing normalized margin/polarization of a ferroelectric capacitor as a function of bake temperature. The polarization here is the difference between the upper and lower lines of the hysteresis loop as shown in FIG. 4. In graph 500, the normalized polarization of a ferroelectric capacitor ranges varies from 1.0 at lower temperatures (e.g., around 25° C.) to approximately 0.3 as temperature increases (e.g., around 275° C.). As described herein, temperature-based depolarization of ferroelectric capacitors is leveraged to enable ferroelectric temperature sensors.

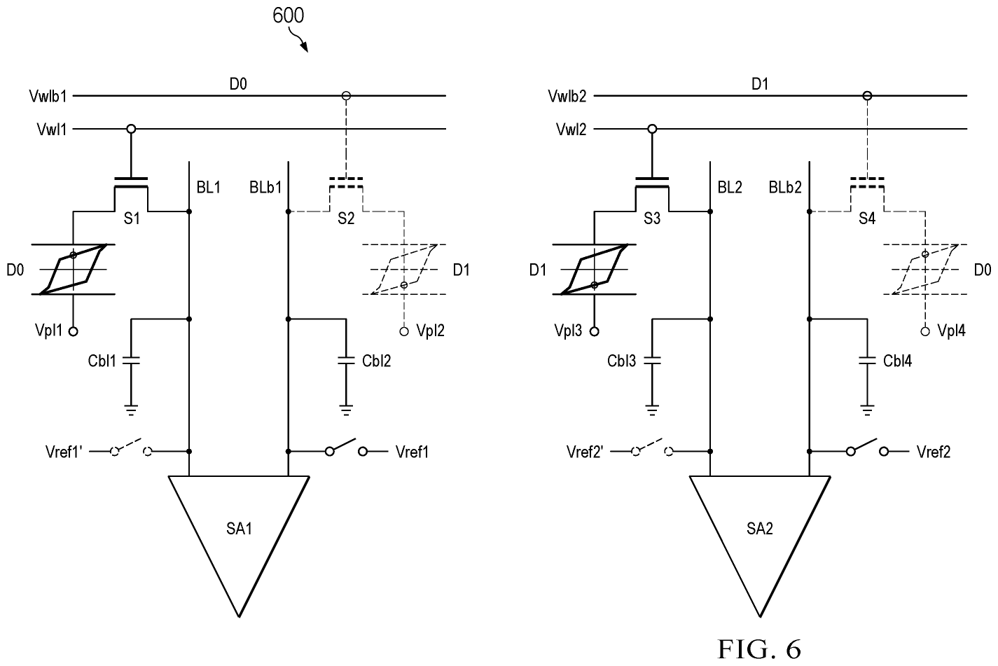

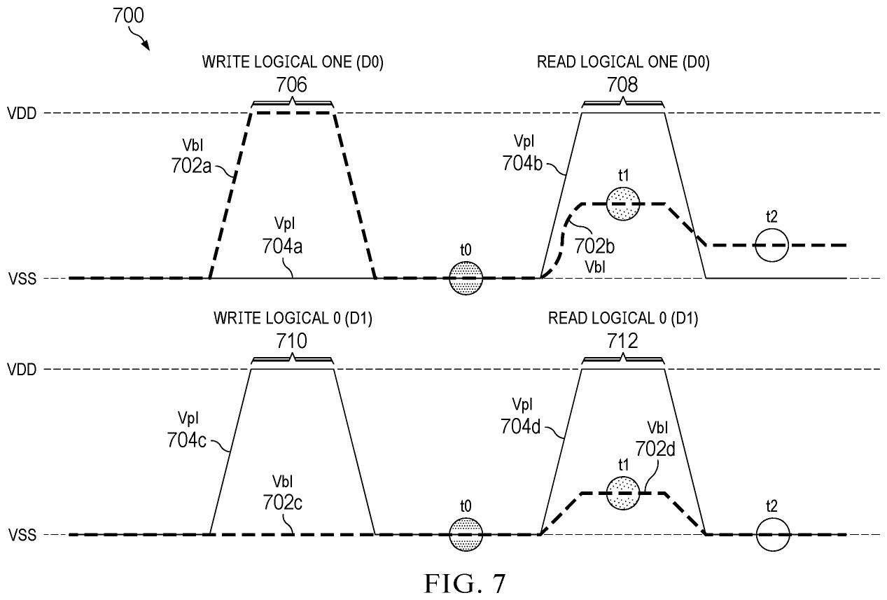

FIG. 6 is a schematic diagram illustrating an example FRAM circuit 600. In the example of FIG. 6, the FRAM circuit 600 can be based on a one-transistor-one-capacitor (1T1C) per bit cell topology, or a two-transistor-two-capacitor (2T2C) per bit cell topology. In the FRAM circuit 600, there are 4 bit cells. The first bit cell includes transistor S1 and ferroelectric capacitor Cbl1. The second bit cell includes transistor S2 and ferroelectric capacitor Cbl2. The third bit cell includes transistor S3 and ferroelectric capacitor Cbl3. The fourth bit cell includes transistor S4 and ferroelectric capacitor Cbl4. The first bit cell is coupled to a first plateline terminal (Vpl1), a first word line (Vwl1), and a first bit line (BL1). Specifically, the transistor S1 is between Vpl1 and BL1. The control terminal of the transistor S1 is coupled to Vwl1. The capacitor Cbl1 is coupled between BL1 and a ground terminal. The second bit cell is coupled to a second plateline terminal (Vpl2), a second word line (Vwlb1), and a second bit line (BLb1). Specifically, the transistor S2 is between Vpl2 and BLb1. The control terminal of the transistor S2 is coupled to Vwlb1. The capacitor Cbl2 is coupled between BLb1 and a ground terminal. The third bit cell is coupled to a third plateline terminal (Vpl3), a third word line (Vwl2), and a third bit line (BL2). Specifically, the transistor S3 is between Vpl3 and BL2. The control terminal of the transistor S3 is coupled to Vwl2. The capacitor Cbl3 is coupled between BL2 and a ground terminal. The fourth bit cell is coupled to a fourth plateline terminal (Vpl4), a fourth word line (Vwlb2), and a fourth bit line (BLb2). Specifically, the transistor S4 is between Vpl4 and BLb2. The control terminal of the transistor S4 is coupled to Vwlb2. The capacitor Cbl4 is coupled between BLb2 and a ground terminal. To perform read operations, the plateline in a FRAM is pulsed. Also, the word line is used to select which capacitor(s) are connected to the bit line and then when the plateline is pulsed the charge from the capacitor is shared with the bit line capacitance

Also, the bit lines BL1 and BLb1 are coupled to inputs of a first sense amplifier (labeled SA1). The bit lines BL2 and BLb2 are coupled to inputs of a second sense amplifier (labeled SA2). As shown, the bit line BLb1 can be coupled to a first Vref (Vref1) terminal via a first switch, the bit line BLb2 can be coupled to a second Vref (Vref2) terminal via a second switch. In a case of 2T2C topology, the bit line BL1 can be coupled to a third Vref (Vref1′) terminal via a third switch, and the bit line BL2 can be coupled to fourth Vref (Vref2′) terminal via a fourth switch.

In a case of 1T1C per bit cell topology of FRAM circuit 600, first and second switches can be first turned on, and bit lines BLb1 and BLb2 are pre-charged to respective reference/threshold voltages Vref1 and Vref2. Typically one of these is Vss. After the pre-charging completes, the first and second switches are turned off, so that bit lines BLb1 and BLb2 are floating. The sense amplifiers can be disabled, or their outputs are discarded, when the bit lines BLb1 and BLb2 are pre-charged. After the first and second switches are turned off, a read operation can be performed on the first bit cell and on the third bit cell. In a case where the ferroelectric capacitor Cbl1 is in the D0 state prior to the read operation (as shown in FIG. 6) and has undergone depolarization, if after-pulse sensing operation is performed (as to be described below), the bit line voltage on BL1 can represent QD0′ charge (after undergoing a small degree of depolarization) or QD0″ charge (after undergoing a substantial degree of depolarization) in FIG. 4, which can also indicate a degree of depolarization in the ferroelectric capacitor.

As part of a margining operation, the sense amplifier can compare the bit line voltage on BL1 with Vref1 on BLb1. If bit line voltage is below Vref1, it can indicate a lower signal level of ferroelectric capacitor Cbl1. Also, for the ferroelectric capacitor Cbl3 which is in the D1 state prior to the read operation, if the bit line voltage on BL2 is above Vref2, it can also indicate a lower signal level of ferroelectric capacitor Cbl3. In some examples, the margining operation can also be performed with different Vref1 and Vref2 values, and the particular Vref1/Vref2 values where a threshold percentage (e.g., 50%) of the capacitors is above (for D0) or below (for D1) the reference voltage can represent a measurement of QD0′ or QD0″ charge in FIG. 4, which in turn represents the degree of depolarization and can represent the excursion temperature.

Also, in a case of 2T2C per bit cell topology of FRAM circuit 600, the pair of bit cells of a 2T2C bit cell can have opposite initial states. For example, first bit cell (including Cbl1) may have initial D0 state, second bit cell (including Cbl2) may have initial D1 state, third bit cell (including Cbl3) may have initial D1 state, and fourth bit cell (including Cbl4) may initial D0 state. To perform a margining operation, bit line BL1 can be pre-charged to a reference/threshold voltage Vref1′ and then left floating afterwards (by connecting and then disconnecting BL1 from the third Vref terminal). Also, bit line BL2 can be pre-charged to a reference/threshold voltage Vref2′ and then left floating afterwards (by connecting and then disconnecting BL2 from the fourth Vref terminal). Read operations can be performed on both the first and second bit cells, and on both the third and fourth bit cells.

The pre-charged voltage Vref1′ can combine with the read out voltage of the first bit cell on bit line BL1, and the pre-charge voltage Vref2′ can combine with the read out voltage of the third bit cell on bit line BL2. The pre-charged voltages Vref1′ and Vref2′ can represent an estimate of a voltage margin between bit cells having opposite switch states, which can indicate whether the bit cells undergo depolarization to the extent that their switch states have flipped. For example, for the 2T2C bit cell on the left, the SA1 output can indicate a pass if the voltage on BL1 exceeds the voltage on BLb1, and indicate a failure if the voltage on BL1 is below the voltage on BLb1. Also, for the 2T2C bit cell on the right, the SA2 output can indicate a pass if the voltage on BL2 is below the voltage on BLb2, and indicate a failure if the voltage on BL2 is above the voltage on BLb2. In some examples, the margining operation can also be performed with different Vref1′ and Vref2′ values, and the particular Vref1/Vref2 values that provide a particular failure rate (e.g., 50%) can represent a measurement of QD0′ or QD0″ charge in FIG. 4, which in turn represents the degree of depolarization and can represent the excursion temperature.

In some examples, to use FRAM bits for temperature excursion sensing, a first pulse read involves: 1) defining groups of bits (e.g., 64), where each group has a minimum # of bits per word line (e.g., 128, 256 or 512); 2) setting Vref for that group; 3) reading all bits on the word line; 4) recording the number of passes/fails; 5) iterate steps 2-4 with varying Vref; 6) recording results including the number of bits that pass/fail for each Vref; and 7) determine a temperature excursion (Texcursion) based the results. For temperature sensing, a shift in D1 (switched polarization) or D0 (non-switched polarization) and either on-pulse sensing or after pulse sensing may be used. In some examples, measuring the BL voltage using D0 (non-switched) with after-pulse sensing has been determined to provide the best signal-to-noise ratio (SNR).

Since the voltage on the bit line and the plateline are independently controlled, the voltage across a ferroelectric capacitor can go negative even though the circuit only uses positive voltages. For example, the voltage on a ferroelectric capacitor will be positive if the capacitor electrode coupled to the plateline is larger than the capacitor electrode coupled to the bit line. During write operations, the bit line is forced to a voltage. During read operations, the word line it turned on, the bit line is floating, and the plate line is pulsed, as described above.

FIG. 7 is a diagram 700 illustrating example write (first pulse) and subsequent read operations (second pulse) of FRAM. In diagram 700, write and read operations include a write logical one (write 1) operation 706 (to set the FRAM bit cell to a D0 state) and a subsequent read logical one (read 1) operation 708. The diagram 700 also shows a write logical zero (write 0) operation 710 (to set the FRAM bit cell to a D1 state) and a subsequent read logical zero (read 0) operation 712. For the write logical one operation 706, the capacitor is written as D1, where the bit line voltage 702a goes to VDD and the plateline voltage Vpl 704a is at VSS in the first pulse before to. For the write logical zero operation 710, the capacitor is written as D0, where the bit line voltage Vbl 702c is at Vss and the plateline voltage Vpl 704c goes to VDD in the first pulse before to.

For read operations after t0, the plateline voltage is pulsed high. For the read logical one operation 708, the plateline voltage Vpl 704b is pulsed high and the bit line voltage Vbl 702b increases to a maximum polarization value at time t1, which is also shown in FIG. 4. Once the plateline voltage Vpl 704b drops to VSS (at the end of the read logical one operation 708), the bit line voltage Vbl 702b settles to a sizeable value at time t2. The bit line voltage Vbl 702b can be sensed and compared with a reference/threshold voltage (e.g., Vref1) by a sense amplifier at t1 or at t2. Sensing at t1 can be an example of on-pulse sensing, and sensing at t2 can be an example of after-pulse sensing. Referring again to FIG. 4, with a small degree of polarization, the bit line voltage Vbl 702b can represent QD0′, and with a large degree of depolarization, the bit line voltage Vbl 702b can represent QD0″. In some examples, the value of the bit line voltage Vbl 702b can be determined by comparing the bit line voltage Vbl 702b from different groups of bit cells with different Vref1s. A particular Vref1 value that provides a particular failure rate or a particular percentage of bit cells (e.g., 50%) having the bit line voltage Vbl 702b below Vref1 can represent the degree of depolarization and can represent the excursion temperature.

Also, for the read logical zero operation 712, the plateline voltage Vpl 704d is pulsed high and the bit line voltage Vbl 702d increases to a maximum polarization value at time t1. Once the plateline voltage Vpl 704d drops to VSS (at the end of the read logical zero operation 712, the bit line voltage Vbl 702d settles to near VSS at time t2. The bit line voltage Vbl 702d can be sensed and compared with a reference/threshold voltage (e.g., Vref2) by a sense amplifier at t1 (on-pulse sensing) or at t2 (after-pulse sensing). In some examples, the value of the bit line voltage Vbl 702d can be determined by comparing bit line voltage Vbl 702d from different groups of bit cells with different Vref2s. A particular Vref2 value that provides a particular failure rate or a particular percentage of bit cells (e.g., 50%) having the bit line voltage Vbl 702d above Vref2 can represent the degree of depolarization and can represent the excursion temperature (if temperature excursion occurs).

Also, as described above, in a case of 2T2C, a reference voltage (e.g., Vref1′) is added to the bit line voltage Vbl 702b, and the combined voltage is then compared with the bit line voltage Vbl 702d voltage to determine a voltage margin/difference between bit line voltage Vbl 702b (representing read 1) and the bit line voltage Vbl 702d (representing read 0). In some examples, different Vref1's can be provided to different groups of 2T2C bit cells to measure the voltage margin. The Vref1′ that provides a particular failure rate (e.g., 50%) can represent the voltage margin/difference, which also reflects the degree of depolarization and the excursion temperature (if temperature excursion occurs).

In some examples, the ferroelectric memory bit cells of a FRAM are organized as an array with each word line in one direction and bit lines in another direction (e.g., perpendicular to the word lines). All of the ferroelectric memory bit cells coupled to a world line have their transistors turned on when the word line voltage is applied. The sense amplifiers are connected to the bit lines as described in FIG. 6. During a read, a single word line is activated and all of the sense amplifiers connected to the array are read. As an example, an array of ferroelectric memory bit cells may have 256 or 512 word lines, and the number of sense amplifiers read for each word line may be 16, 32, 64 or 128.

For FRAM memories, to perform a read operation, a word line voltage is applied and the plateline is pulsed. FRAM can be read with the plateline high (on-pulse read mode) or after it has dropped to ground (after-pulse read mode).

In some examples, D0 or D1 in the plateline is read using an after-pulse read mode when the plateline has returned to ground. For D0 sensing, the charge remaining on the bit line after the plateline pulse is applied can represent the relaxation or temperature excursion charge, which also indicates the degree of depolarization. To measure the charge, the bit line voltages of different groups of ferroelectric memory bit cells can be compared with different Vref voltages (which are set based on whether after-pulse or on-pulse sensing is performed), and the particular Vref that provide a particular failure rate (e.g., 50%) can represent the degree of depolarization and can represent the excursion temperature, as described above.

In some examples, in lieu of (or in addition to) the aforementioned margining operations, the bit line voltages can also be measured directly with an analog-to-digital converter (ADC). For example, the sense amplifiers or comparators can be part of an ADC.

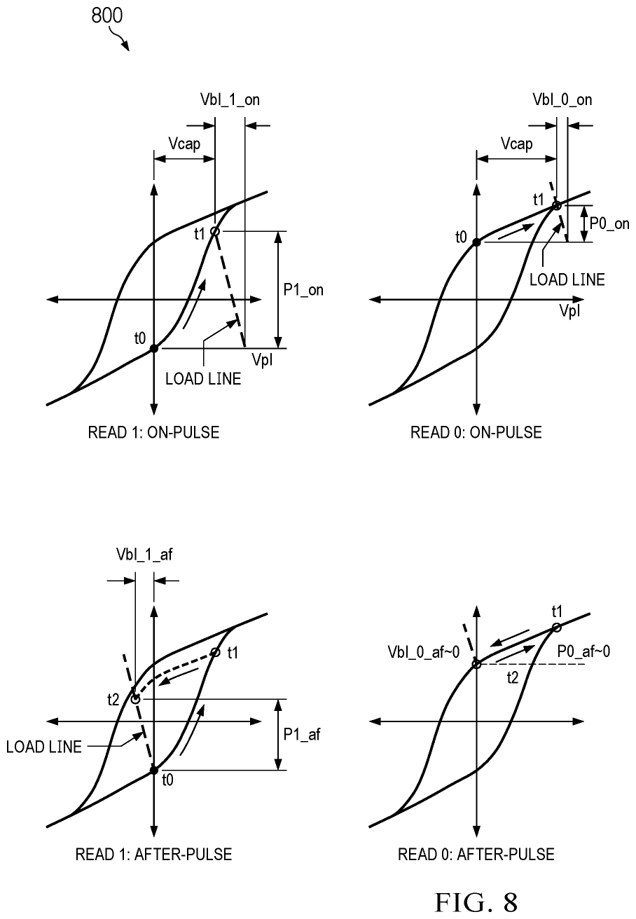

FIG. 8 is a diagram 800 illustrating example charge and voltage states of a ferroelectric capacitor during read operations of FRAM. During read 1 and read 0 operations, the voltage across a ferroelectric capacitor is the difference between the bit line voltage and the plate line voltage. The actual voltage is found, as shown in diagram 800, using a load line which graphically represents the voltage sharing between the ferroelectric capacitor and the bit line capacitor. Also represented in diagram 800 are the on-pulse read mode and the after-pulse read mode. An on-pulse read triggers the sense amplifier when the plateline is high. An after-pulse read triggers the sense amplifier when the plateline is back to ground. The on-pulse read option has the advantage of being faster and providing a larger signal level. The after-pulse read option has the advantage of being much simpler to set the sense amplifier reference level. Also, the variability in the after-pulse data 0 is much smaller than the on-pulse data 0.

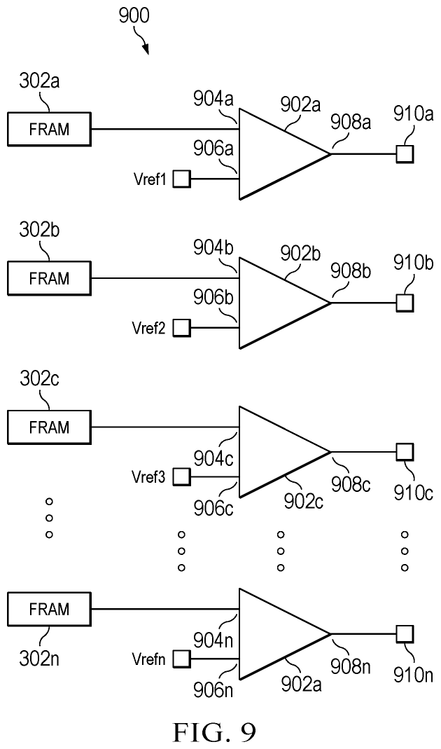

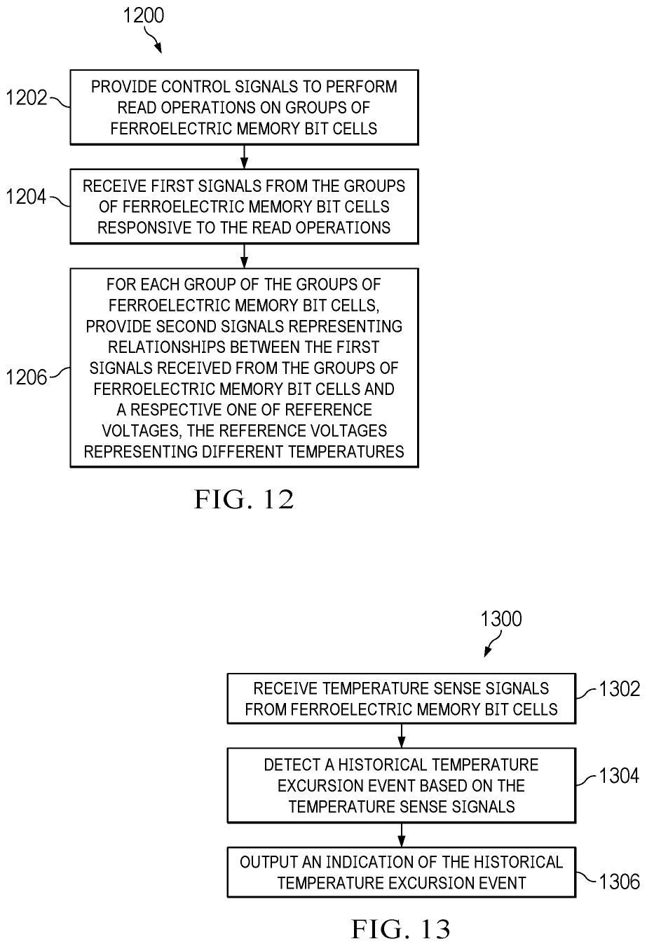

FIG. 9 is a diagram 900 illustrating example components of a ferroelectric temperature sensor. The components in the diagram 900 may be part of, for example, the ferroelectric temperature sensor 202 of FIG. 2. In the example of FIG. 9, the diagram 900 includes FRAM circuits 302a to 302n. The FRAM circuits 302a to 302n are example components of the FRAM circuitry 302 in FIG. 3. In some examples, each of the FRAM circuits 302a to 302n corresponds to a group of ferroelectric memory bit cells. The outputs of the FRAM circuits 302a to 302n are coupled to respective first inputs 904a to 904n of comparators 902a to 902n. In some examples, the comparators 902a to 902n are part of FRAM interface circuit 306. In other examples, the comparators 902a to 902n are part of the FRAM circuitry 302 (e.g., the comparators 902a to 902n may be examples of the sense amplifiers SA1 and SA2 in FIG. 6). The respective second inputs 906a to 906n of the comparators 902a to 902n receive a respective reference voltage of reference voltage Vref1 to Vrefn. The comparator outputs 908a to 9098n of the comparators 902a to 902n are coupled to respective processing outputs 910a to 910n. In other words, the comparison results are provided to a processing circuit, such as the processing circuit 312 in FIGS. 3 and 12, via the processing outputs 910a to 910n.

In some examples, the FRAM circuits 302a to 302n are subject to write operations. Later, the FRAM circuits 302a to 302n are subject to read operations such as the read 1 and read 0 operations described herein. In the description below, it is assumed that each FRAM circuits 302a to 302n is initially set in the D0 state. The results of the read operations are provided to the respective comparators 902a to 902n. The output of each the comparators 902a to 902n indicates a pass/fail status of a respective one of the FRAM circuits 302a to 302n. For example, if a read operation output of the FRAM circuit 302a is greater than Vref1 then the FRAM circuit 302a has a pass status, if a read operation output of the FRAM circuit 302b is greater than Vref2 then FRAM circuit 302b has a pass status, and so on. After FRAM read operations are complete, the pass/fail status of each of the FRAM circuits 302a to 302n is provided to the processing outputs 910a to 910n. These pass/fail status results are stored, analyzed, and interpreted by a processing circuit, such as the processing circuit 312 in FIGS. 3 and 12, to determine a maximum temperature or temperature excursion between the time of the FRAM write operations and the subsequent FRAM read operations.

In some examples, each Vref is generated internally by the memory interface circuit. Without limitation, the memory interface circuit may include an adjustable voltage source or digital-to-analog converter (DAC) to generate different Vref values. The Vref values selected may vary depending on a target temperature or temperature range to be sensed. As an example, a target temperature range may be 100° C. to 180° C. In some examples, temperature is detected using D0 after-pulse signaling. As an arbitrary example (not experimental), suppose FRAM testing shows that 100° C. is correlated to an D0 readout of 30 mV, 140° C. is correlated to an D0 readout of 40 mV, and 180° C. is correlated to a D0 readout of 80 mV. In such case, ferroelectric memory bit cell failures may be analyzed for Vref set to 10 mV up to 100 mV in 5 mV steps. The first Vref that results in a threshold amount of ferroelectric memory bit cell failures (e.g., 50%) is found. In some examples, a curve fit or linear approximation may be used to identify the threshold amount of ferroelectric memory bit cell failures. The Vref that results in the threshold amount of ferroelectric memory bit cell failures is correlated to temperature based on previous testing. Depending on the sensitivity needed the size of the Vref steps can be smaller such as 1 mV or 2 mV.

In some examples, a FRAM-based temperature sensor is based on measuring a single capacitor and whether the signal is greater than or less than Vref. One read operation is performed per capacitor. This read indicates if that bit had a signal level above or below Vref. In some examples, FRAM and a micro-controller (MCU) are used to perform FRAM reads and analyze pass/fail results. By obtaining and analyzing the pass/fail results of many FRAM bit cell reads, a maximum temperature, or a target temperature excursion is determined.

In some examples, D0 reads are performed on many FRAM bit cells, and the readout voltages is compared with different Vrefs. For each readout voltage less than a given positive Vref, a failure is assumed. In other examples, D1 reads are performed on many FRAM bit cells, and the readout voltages are compared with different Vrefs. If a given readout voltage is greater than a given negative Vref, a failure is assumed. The Vref that results in a target amount or percentage of readout failures is correlated to temperature based on previous testing.

FRAM-based temperature sensors may be affected by time. Accordingly, if the amount of time between write operations and the later read operations for a FRAM-based temperature sensor is beyond a first threshold, the results may be discounted. If the amount of time between write operations and the later read operations for a FRAM-based temperature sensor is less than the first threshold and greater than a second threshold, the results may be calibrated or adjusted to account for time element. If the amount of time between write operations and the later read operations for a FRAM-based temperature sensor is less than the second threshold, the results may be interpreted as valid without calibration or adjustment to account for the time element.

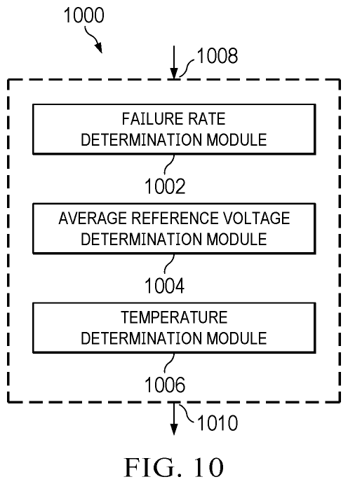

FIG. 10 is a diagram illustrating an example processing circuit 1000. The processing circuit 1000 is an examples of the processing circuit 312 of FIGS. 3 and 12. In some examples, the processing circuit 1000 has processing inputs 1008 and a processing output 1010. In some examples, the processing inputs 1008 are coupled to or in communication with the processing outputs 910a to 910n in FIG. 9.

The processing circuit 1000 includes a failure rate determination module 1002, an average reference voltage determination module 1004, and a temperature determination module 1006. Each of the failure rate determination module 1002, the average reference voltage determination module 1004, and the temperature determination module 1006 may be software modules and/or hardware modules. Example hardware of the processing circuit 1000 includes a processor, memory, registers, logic gates, and/or other hardware. Example software of the processing circuit 1000 includes instructions stored by memory, where the memory is in communication with a processor.

The failure rate determination module 1002 operates to: obtain Vref vs FRAM read comparisons results at the processing inputs 1008; interpret each comparison result as a pass/fail status of each FRAM circuit; and determine a failure rate of different groups of FRAM circuit based on the pass/fail status. The average reference voltage determination module 1004 operates to: receive the Vref values used by the comparators that compare FRAM read results with Vref (e.g., comparators 902a to 902n); and determine the average Vref based on the received Vref values. The temperature determination module 1006 operates to: determine a maximum temperature or a temperature excursion based on the determined failure rate of the different groups of FRAMs and the average Vref; and providing the maximum temperature or the temperature excursion at the processing output 1010. In different examples, the maximum temperature or the temperature excursion at the processing output 1010 is stored for later use, displayed, used to trigger an audio alert or visual alert, used to control a circuit, device, or motor, and/or other uses.

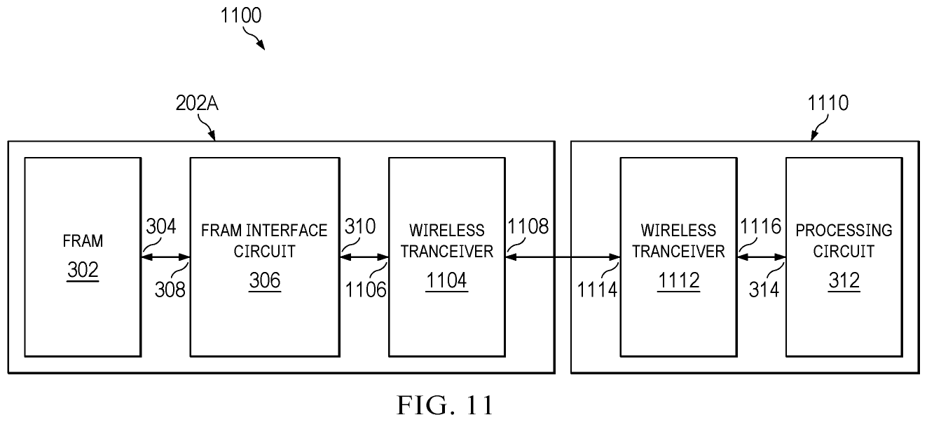

FIG. 11 is a diagram illustrating another example system 1100. In the example of FIG. 11, the system 1100 includes a ferroelectric temperature sensor 202A in communication with a controller 1110. The ferroelectric temperature sensor 202A includes the FRAM circuitry 302, the FRAM interface circuit 306, and a first wireless transceiver 1104. The controller 1110 includes a second wireless transceiver 1112 and the processing circuit 312. As shown, the first wireless transceiver 1104 has a first communication interface 1106 and a second communication interface 1108. The second wireless transceiver 1112 has a first communication interface 1114 and a second communication interface 1116. As shown, the first communication interface 1106 of the first wireless transceiver is coupled to the second communication interface 310 of the FRAM interface circuit 306. The second communication interface 1108 of the first wireless transceiver 1104 send data to or receives data from the first communication interface 1114 of the second wireless transceiver 1112. The second communication interface 1116 of the second wireless transceiver 1112 is coupled to the communication interface 314 of the processing circuit 312.

In some examples, the controller 1110 transmits data to the ferroelectric temperature sensor 202A via the second wireless transceiver 1112 and the first wireless transceiver 1104. The FRAM interface circuit 306 performs write operations to store the data in the FRAM circuitry 302 as polarization states of the related ferroelectric capacitors. The ferroelectric temperature sensor 202A is later queried by the controller 1110 to obtain temperature indicators as described herein. For example, the FRAM interface circuit 306 may perform read 1 and read 0 operations to read the data in the FRAM circuitry 302 from which the pass rate or failure rate of groups of ferroelectric memory bit cells is determined. As described herein, the pass rate or failure rate of groups of ferroelectric memory bit cells is a temperature indicator. Based on such temperature indicators, the controller 1110 determines a maximum temperature and/or a temperature excursion status detected by the ferroelectric temperature sensor 202A.

In some examples, an apparatus includes: groups of ferroelectric memory bit cells (e.g., the FRAM circuitry 302 in FIGS. 3 and 11, or the FRAM circuits 302a to 302n in FIG. 9); and memory interface circuitry (e.g., the FRAM interface circuit 306 in FIGS. 3 and 11) having processing outputs (e.g., the second communication interface 310 herein) and memory access terminals (e.g., the first communication interface 308 herein). The memory access terminals are coupled to the groups of ferroelectric memory bit cells. The memory interface circuitry is configured to: provide control signals (e.g., a plateline voltage and/or a word line voltage) via the memory access terminals to perform read operations on the groups of ferroelectric memory bit cells; receive first signals (e.g., the outputs from each sense amplifier or comparison results of the plateline voltage and the bit line voltage as described in FIG. 7) from the groups of ferroelectric memory bit cells via the memory access terminals from the read operations; and for each group of the groups of ferroelectric memory bit cells, provide second signals (e.g., the comparison results from the comparators 902a to 902n) representing relationships between the first signals received from the group of ferroelectric memory bit cells and a respective one of reference voltages at the processing outputs, the reference voltages representing different temperatures. In some examples, the memory interface circuitry is configured to generate the second signals based on comparing the first signals from the different groups of ferroelectric memory bit cells with the reference voltages.

In some examples, each ferroelectric memory bit cell of the groups of ferroelectric memory bit cells has a respective word terminal (e.g., the word lines Vwl1, Vwlb1, Vwl2, Vwlb2 in FIG. 6) and a respective plate terminal (e.g., the plateline terminals Vpl1, Vpl2, Vpl3, Vpl4 in FIG. 6). The plate terminals of the groups of ferroelectric memory bit cells is coupled to the memory access terminal. In such examples, the apparatus also includes groups of switches (e.g., switches S1, S2, S3, and S4 in FIG. 6) and bit lines (e.g., bits lines BL1, BLb1, BL2, and BLb2 in FIG. 6). Each switch of each group of the groups of switches coupled between the plate terminal of a respective ferroelectric memory bit cell of a respective group of ferroelectric memory bit cells and a respective one of the bit lines. The switches have control terminals coupled to respective word terminals. The memory interface circuitry includes comparators (e.g., the comparators 902a to 902n in FIG. 9) configured to generate the second signals based on comparing the first signals from the different groups of ferroelectric memory bit cells with the reference voltages, each of the comparators has a first input (e.g., first inputs 904a to 904n in FIG. 9), a second input (e.g., second inputs 906a to 906n in FIG. 9), and a comparator output (e.g., comparator outputs 908a to 908n in FIG. 9). The first input of each of the comparators is coupled to a respective one of the bit lines. The comparator outputs are coupled to the processing outputs (e.g., processing outputs 910a to 910n in FIG. 9), and each of the comparators is configured to: receive a respective one of the first signals from a respective group of ferroelectric memory bit cells at its first input; receive a respective one of the reference voltages at its second input; and provide a respective one of the second signals at its comparator output.

In some examples, the memory interface circuitry is configured to perform read operations on each group of the groups of ferroelectric memory bit cells based on: providing, as part of the control signals, selection signals to enable each group of the groups of switches to connect the plate terminals of the respective groups of ferroelectric memory bit cell to one of the bit lines sequentially at different times; providing, as part of the control signals, pulse signals to the plate terminals of the respective groups of ferroelectric memory bit cell sequentially at different times; and after each of the pulse signals, enabling each comparator to compare the first signal provided by each ferroelectric memory bit cell of the group of ferroelectric memory bit cells with the respective one of the reference voltages to generate the second signal for ferroelectric memory bit cell. In some examples, the groups of ferroelectric memory bit cells and the memory interface circuitry are part of an integrated circuit, and the integrated circuit further includes a wireless transceiver coupled to the memory interface circuitry. In such examples, the memory interface circuitry is configured to: receive a memory read request from the wireless transceiver; and transmit the second signals in response to the memory read request via the wireless transceiver. In some examples, the memory interface circuitry is configured to receive power from the wireless transceiver.

In some examples, the processing output is a first processing output, and the apparatus further includes a processing circuit (e.g., the processing circuit 312 in FIGS. 3 and 12, or the processing circuit 1000 in FIG. 10) having a second processing output (e.g., the processing output 1010 in FIG. 10). The processing circuit is configured to: detect, based on the second signals, a historical temperature excursion event; and provide an indication of the historical temperature excursion event at the second processing output. In some examples, the processing circuit is configured to provide a third signal based on the second signal representing a temperature of the apparatus in the historical temperature excursion event at the second processing output.

In some examples, the processing circuit is configured to: for each group of the groups of ferroelectric memory bit cells, determine a failure rate based on whether the respective second signals of the group of ferroelectric memory bit cells indicate that the respective first signals of the group of ferroelectric memory bit cells exceeds or is below the respective one of the reference voltages; and determine the temperature based on the failure rates and the reference voltages. In some examples, the processing circuit is configured to determine the temperature based on: determining, based on the failure rates and the reference voltages, an average reference voltage that results in at least a threshold failure rate among the groups of ferroelectric memory bit cells; and determining the temperature based on the average reference voltage.

In some examples, the apparatus includes a wireless transceiver (e.g., the second wireless transceiver 1112 in FIG. 11) coupled to the processing circuit. In such examples, the processing circuit configured to: transmit a memory access request to the memory interface circuitry via the wireless transceiver; and receive the second signals from the memory interface circuitry via the wireless transceiver after transmitting the memory access request.

In some examples, an apparatus includes a processing circuit (e.g., the processing circuit 312 in FIGS. 3 and 12, or the processing circuit 1000 in FIG. 10) having a processing output (e.g., the processing output 1010 in FIG. 10). In such examples, the processing circuit is configured to: receive temperature sense signals from ferroelectric memory bit cells (e.g., the 1T1C bit cells of FRAM circuit 600 in FIG. 6, or 2T2C bit cells as described herein); detect a historical temperature excursion event based on the temperature sense signals; and provide an indication of the historical temperature excursion event at the processing output.

In some examples, the processing output is a first processing output, and the apparatus also includes: a sensor (e.g., the ferroelectric temperature sensor 202 in FIGS. 2A and 2B, the ferroelectric temperature sensor 202A in FIG. 11) in communication with the processing circuit (e.g., the processing circuit 312 in FIGS. 3 and 12, or the processing circuit 1000 in FIG. 10). The sensor includes: groups of ferroelectric memory bit cells (e.g., the FRAM circuitry 302 in FIGS. 3 and 12, the FRAM circuits 302a to 302n in FIG. 3, groups of the 1T1C bit cells of FRAM circuit 600 in FIG. 6, or groups of 2T2C bit cells as described herein); memory interface circuitry (e.g., the FRAM interface circuit 306 in FIGS. 3 and 12, or related components such as the comparators 902a to 902n) and the processing outputs 910a to 910n) having second processing outputs (e.g., the second communication interface 310, or the processing outputs 910a to 910n in FIG. 9) and memory access terminals (e.g., the first communication interface 308). The memory access terminals are coupled to the groups of ferroelectric memory bit cells, and the memory interface circuitry is configured to: provide control signals via the memory access terminals to perform read operations on the groups of ferroelectric memory bit cells; receive first signals from the groups of ferroelectric memory bit cells via the memory access terminals from the read operations; and for each group of the groups of ferroelectric memory bit cells, provide the temperature sense signals representing relationships between the first signals received from the group of ferroelectric memory bit cells and a respective one of reference voltages at the processing outputs, the reference voltages representing different temperatures.

In some examples, the apparatus also includes a first wireless transceiver (e.g., the second wireless transceiver 1112 in FIG. 11) coupled to the processing circuit. In such examples, the sensor includes a second wireless transceiver (e.g., the first wireless transceiver 1104 in FIG. 11), and the sensor is in communication with the processing circuit via the first and second wireless transceivers. In some examples, the sensor is configured to: detect temperature excursions above 100° C.; and provide a temperature excursion indicator to the processing circuit in response to a wireless query.

FIG. 12 is a flowchart illustrating an example method 1200 for a ferroelectric temperature sensor. The method 1200 is performed, for example, by the ferroelectric temperature sensor 200 in FIG. 2, or the ferroelectric temperature sensor 202A in FIG. 11. As shown, the method 1200 includes providing control signal to perform read operations on groups of ferroelectric memory bit cells at block 1202. Each ferroelectric memory bit cell can be a 1T1C or 2T2C cell as shown in FIG. 6, and the control signals can include pulses on platelines and selection signals on word lines.

At block 1204, the first signals (e.g., bit line voltages) are received from the groups of ferroelectric memory bit cells responsive to the read operations. At block 1206, second signals (e.g., sense amplifier or comparator outputs) are provided for each group of the groups of ferroelectric memory bit cells, where the second signals represent relationships between the first signals received from the groups of ferroelectric memory bit cells and a respective one of reference voltages, and where the reference voltages represent different temperatures.

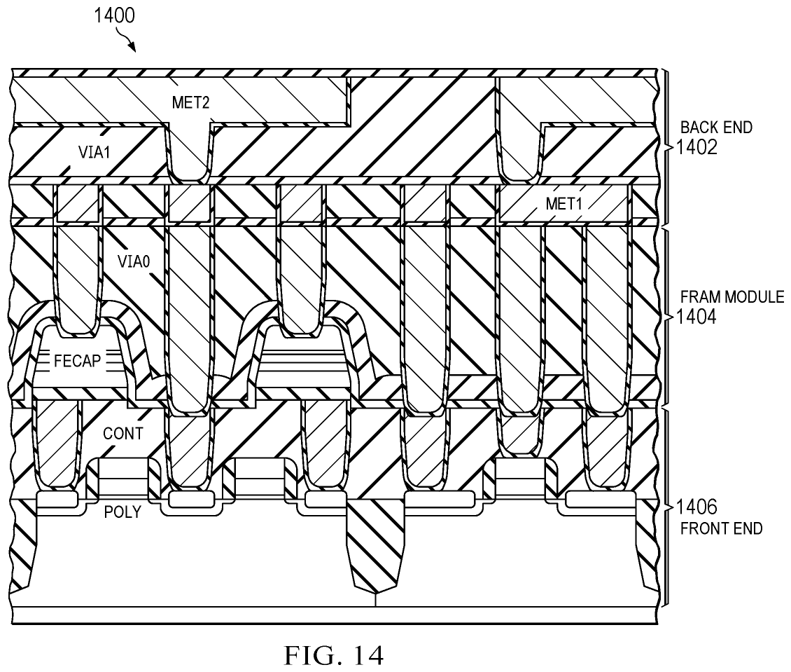

FIG. 13 is a flowchart illustrating an example method 1300 for detecting a historical temperature excursion event. For example, the method 1300 may be performed by the processing circuit 312 in FIGS. 3 and 12, or the processing circuit 1000 in FIG. 10. As shown, the method 1300 includes receiving temperature sense signals from ferroelectric memory bit cells at block 1302. At block 1304, a historical temperature excursion event is detected based on the temperature sense signals. At block 1306, an indication of the historical temperature excursion event is output. The output indication may result in a temperature value being displayed, a temperature excursion alert being provided as an audio signal or a visual signal, a control signal for a circuit being generated (e.g., to turn on the circuit, to turn off the circuit, to change a parameter of the circuit), etc. In some examples, the method 1200 of FIG. 12 and the method 1300 of FIG. 13 are performed together. For example, the method 1200 may be initiated by a request from the processor related to method 1300 or a request from the related controller (e.g., the controller 1110 in FIG. 11). After the method 1200 is complete in response to a request, the method 1300 is performed by the processor.

FIG. 14 is a cross-sectional view illustrating an example integrated circuit (IC) 1400 that includes a ferroelectric temperature sensor. As shown, the IC 1400 includes a back end layer 1402, a FRAM module layer 1404, and a front end layer 1406. In some examples, the FRAM module layer 1404 includes the FRAM circuitry 302 and the FRAM interface circuit 306 used to provide a ferroelectric temperature sensor.

One of the challenges in making an embedded memory is combining the logic processing and masks with that needed for the non-volatile memory. This is particularly difficult for flash and EEPROM because the additional processing to make the memory transistors modifies the properties of the logic transistors. It is therefore necessary to modify the logic transistor processing when adding non-volatile memory capability in order to maintain the intended transistor properties. Therefore the development of these types of embedded memory is significantly more complicated that just the memory itself.

The ideal embedded memory would therefore require no changes the standard logic processes and this is achieved without any changes in the required electrical characteristics used by designs. If the electrical characteristics are much different then all of the logic designs for the combined embedded memory will need to be redone at significant expense. This ideal embedded memory should be obtained with a minimum number of added masks over those required by the logic process.

In some examples, the front end layer 1406 includes transistors and contacts (CONT). The back end layer 1402 includes conductive layers (e.g., MET1 and above). This standard dividing line is important for eFRAM because the process temperature at the end of the front end processes is typically 650° C. at the 130 nm generation while the back end processes typically have a maximum temperature of 400 or 450° C. The process temperatures for ferroelectric capacitors using PZT can be achieved at ˜600° C. so it is possible to add the FRAM module layer 1404 using two added masks at the transition between front end and back end processes. The low process temperature of lead zirconate titanate (PZT) versus other ferroelectrics is one of the principal reasons that it currently the preferred ferroelectric material for FRAM. PZT is not the only ferroelectric that works for temperature excursion sensing. All ferroelectric materials have a temperature dependent polarization loss like PZT. Example ferroelectric materials include HfOx based ferroelectrics such as Si doped HfOx, HfZrOx and many others.

In some examples, the FRAM module layer 1404 is fabricated using an etch process that can etch all of the many layers in the ferroelectric stack with one mask. In addition, the ferroelectric stack must be deposited on top of the standard logic W contacts. This requires development of excellent diffusion barriers to prevent the oxidation of the W by the ferroelectric deposition and anneal processes. Another mask used to fabricate the FRAM module layer 1404 is referred to as VIA0. This mask electrically connects a first metal layer (MET1) to top of the ferroelectric capacitor and standard logic contacts as well. In this scheme the capacitor is under the bit line which is typically run in a second metal layer (MET2).

In alternative examples, additional masks may be used to fabricate planar (rather than stacked) ferroelectric capacitors in the FRAM module layer 1404, which are smaller. For example, the use of self-aligned bit line contacts (BL_CONT) reduces the minimum CONT to POLY space and hence minimum cell area. The use of a W local interconnect allows a capacitor over bit line (COB) layout that increases the capacitor area for a given cell area. These additional process modifications are not desirable for an embedded memory process because they increase the # of added masks (+6 masks in this example).

Two FRAM cell variations are based on whether the ferroelectric capacitor is over the bitline (COB) or under the bitline (CUB). The CUB layout creates smaller capacitor area compared to the COB layout. It is possible to significantly increase the ferroelectric capacitor (FECAP) area efficiency for CUB layouts by modifying the transistor size and CONT location. In such examples, BL_CONT is now at the corners of the capacitors resulting in sufficient FECAP to CONT space because of the natural rounding of the FECAP. It is possible to put small notches at the corners of the capacitors to increase the space without significantly decreasing eh capacitor area. This cell layout maximizes the FECAP area efficiency for embedded friendly CUB layout. The FECAP area is one of the critical parameter not only from a signal level on the bit line but also due to variability in capacitor signal.

In some examples, fabrication of the FRAM module layer 1404 starts with standard logic 130 nm front end process flow. In some examples, this process is stopped after W CMP but instead of starting MET1 process an FRAM process module is instead inserted. The first step in that FRAM process module may be the deposition of the ferroelectric stack. All of the layers in this stack serve one or more purposes. From the bottom the stack layers and purposes are sputtered titanium aluminum nitride (TiAlN) 50 nm bottom electrode diffusion barrier, sputtered iridium (Ir) 70 nm bottom electrode, metal organic chemical vapor deposition (MOCVD) Lead (Zr0.3, Ti0.7) O3 70 nm ferroelectric, sputtered iridium oxide (IrOx) 30 nm top electrode, sputtered Ir 20 nm top electrode contact, and sputtered TiAlN 300 nm hardmask. The MOCVD PZT achieves reliable ferroelectric properties at low voltages.

In some examples, a FECAP mask is used to pattern photoresist whose pattern is then transferred to the hardmask. All of the rest of the ferroelectric layers are then etched using the hardmask. This is a difficult process because there are no volatile Ir species. Therefore, a very physical etch process may be used, resulting in a sloped etch profile. In some examples, the next step is to deposit aluminum oxide (AlOx) diffusion barrier by atomic layer deposition (ALD). The AlOx not only prevents H2 present during later process steps from diffusing to the PZT and degrading its properties but also prevents Pb in the PZT from diffusing into the silicon nitride (SiN) and silicon oxide (SiO₂) layers nearby. In some examples, a SiN VIA0 etch stop layer is then deposited followed by TEOS SiO2 followed by chemical mechanical polishing (CMP) to create a planar top surface for photolithography of VIA0. These processes therefore create the interlayer dielectric for VIA0. The VIA0 is then created using similar processes as were used to create CONT. In addition, the VIA0 etch process etches to two different depths (top of FECAP and top of CONT) which is similar to the CONT etch process (top of gate and to Si channel). Both processes use the SiN etch stop and the same type of SiO2 etch process that etches SiO2 but not SiN. At this point, standard logic metal backend processes are used. The surface of the VIA0 is the same as the surface of CONT so there are no issues that require any modification of any of the metallization processes.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

While the use of particular transistors is described herein, other transistors (or equivalent devices) may be used instead with little or no change to the remaining circuitry. For example, a field effect transistor (“FET”) such as an NFET or a PFET, a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control terminal and its first and second terminals. In the context of a FET, the control terminal is the gate, and the first and second terminals are the drain and source. In the context of a BJT, the control terminal is the base, and the first and second terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

1. An apparatus comprising:
groups of ferroelectric memory bit cells; and
memory interface circuitry having processing outputs and memory access terminals, the memory access terminals coupled to the groups of ferroelectric memory bit cells, and the memory interface circuitry configured to:
provide control signals via the memory access terminals to perform read operations on the groups of ferroelectric memory bit cells;
receive first signals from the groups of ferroelectric memory bit cells via the memory access terminals from the read operations; and
for each group of the groups of ferroelectric memory bit cells, provide second signals representing relationships between the first signals received from the group of ferroelectric memory bit cells and a respective reference voltage of the reference voltages at the processing outputs, the reference voltages representing different temperatures.

2. The apparatus of claim 1, wherein the memory interface circuitry is configured to generate the second signals based on comparing the first signals from different groups of the groups of ferroelectric memory bit cells with the reference voltages.

3. The apparatus of claim 2, wherein:
each ferroelectric memory bit cell of the groups of ferroelectric memory bit cells has a respective word terminal and a respective plate terminal, the plate terminals of the groups of ferroelectric memory bit cells coupled to respective terminals of the memory access terminals;
the apparatus further comprises groups of switches and bit lines; and
each switch of each group of the groups of switches coupled between the plate terminal of a respective ferroelectric memory bit cell of a respective group of ferroelectric memory bit cells and a respective bit line of the bit lines, the switches having control terminals coupled to respective word terminals.

4. The apparatus of claim 3, wherein the memory interface circuitry includes comparators configured to generate the second signals based on comparing the first signals from different groups of the groups of ferroelectric memory bit cells with the reference voltages, each of the comparators has a first input, a second input, and a comparator output, the first input of each of the comparators coupled to a respective bit line of the bit lines, the comparator outputs coupled to the processing outputs, and each of the comparators is configured to:
receive a respective signal of the first signals from a respective group of ferroelectric memory bit cells at its first input;
receive a respective reference voltage of the reference voltages at its second input; and
provide a respective signal of the second signals at its comparator output.

5. The apparatus of claim 4, wherein the memory interface circuitry is configured to perform read operations on each group of the groups of ferroelectric memory bit cells based on:
providing, as part of the control signals, selection signals to enable each group of the groups of switches to connect the plate terminals of respective groups of ferroelectric memory bit cell to a respective bit line of the bit lines sequentially at different times;
providing, as part of the control signals, pulse signals to the plate terminals of the respective groups of ferroelectric memory bit cell sequentially at different times; and
after each of the pulse signals, enabling each comparator to compare the first signal provided by each ferroelectric memory bit cell of the group of ferroelectric memory bit cells with the respective reference voltage of the reference voltages to generate the second signal for ferroelectric memory bit cell.

6. The apparatus of claim 1, wherein the groups of ferroelectric memory bit cells and the memory interface circuitry are part of an integrated circuit, and the integrated circuit further includes a wireless transceiver coupled to the memory interface circuitry, wherein the memory interface circuitry is configured to:
receive a memory read request from the wireless transceiver; and
transmit the second signals in response to the memory read request via the wireless transceiver.

7. The apparatus of claim 6, wherein the memory interface circuitry is configured to receive power from the wireless transceiver.

8. The apparatus of claim 1, wherein the processing output is a first processing output, and the apparatus further comprises a processing circuit having a second processing output, the processing circuit configured to:
detect, based on the second signals, a historical temperature excursion event; and
provide an indication of the historical temperature excursion event at the second processing output.

9. The apparatus of claim 8, wherein the processing circuit is configured to provide a third signal based on the second signal representing a temperature of the apparatus in the historical temperature excursion event at the second processing output.

10. The apparatus of claim 9, wherein the processing circuit is configured to:
for each group of the groups of ferroelectric memory bit cells, determine a failure rate based on whether the respective second signals of the group of ferroelectric memory bit cells indicate that the respective first signals of the group of ferroelectric memory bit cells exceeds or is below the respective reference voltage of the reference voltages; and
determine the temperature based on the failure rates and the reference voltages.

11. The apparatus of claim 10, wherein the processing circuit is configured to determine the temperature based on:
determining, based on the failure rates and the reference voltages, an average reference voltage that results in at least a threshold failure rate among the groups of ferroelectric memory bit cells; and
determining the temperature based on the average reference voltage.

12. The apparatus of claim 8, further comprising a wireless transceiver coupled to the processing circuit, the processing circuit configured to:
transmit a memory access request to the memory interface circuitry via the wireless transceiver; and
receive the second signals from the memory interface circuitry via the wireless transceiver after transmitting the memory access request.

13. An apparatus comprising:
a processing circuit having a processing output, the processing circuit configured to:
receive temperature sense signals from ferroelectric memory bit cells;
detect a historical temperature excursion event based on the temperature sense signals; and
provide an indication of the historical temperature excursion event at the processing output.

14. The apparatus of claim 13, wherein the processing output is a first processing output, and the apparatus further comprises:
a sensor in communication with the processing circuit, the sensor including:
groups of ferroelectric memory bit cells;
memory interface circuitry having second processing outputs and memory access terminals, the memory access terminals coupled to the groups of ferroelectric memory bit cells, and the memory interface circuitry configured to:
provide control signals via the memory access terminals to perform read operations on the groups of ferroelectric memory bit cells;
receive first signals from the groups of ferroelectric memory bit cells via the memory access terminals from the read operations; and
for each group of the groups of ferroelectric memory bit cells, provide the temperature sense signals representing relationships between the first signals received from the group of ferroelectric memory bit cells and a respective reference voltage of reference voltages at the processing outputs, the reference voltages representing different temperatures.

15. The apparatus of claim 14, further comprising a first wireless transceiver coupled to the processing circuit, the sensor includes a second wireless transceiver, and the sensor is in communication with the processing circuit via the first and second wireless transceivers.

16. The apparatus of claim 15, wherein the sensor is configured to:
detect temperature excursions above 100° C.; and
provide a temperature excursion indicator to the processing circuit in response to a wireless query.

17. A method comprising:
providing, by a sensor, control signals to perform read operations on groups of ferroelectric memory bit cells;
receiving, by the sensor, first signals from the groups of ferroelectric memory bit cells responsive to the read operations; and
for each group of the groups of ferroelectric memory bit cells, providing, by the sensor, second signals representing relationships between the first signals received from the group of ferroelectric memory bit cells and a respective reference voltage of reference voltages, the reference voltages representing different temperatures.

18. The method of claim 17, further comprising:
receiving, by a processor, the second signals;
detecting, by the processor, a historical temperature excursion event based on the second signals; and
outputting, by the processor, an indication of the historical temperature excursion event.

19. A method comprising:
receiving, by a processor, temperature sense signals from ferroelectric memory bit cells;
detecting, by the processor, a historical temperature excursion event based on the temperature sense signals; and
outputting, by the processor, an indication of the historical temperature excursion event.

20. The method of claim 19, further comprising:
providing, by a sensor, control signals to perform read operations on groups of the ferroelectric memory bit cells;
receiving, by the sensor, first signals from the groups of ferroelectric memory bit cells responsive to the read operations; and
for each group of the groups of ferroelectric memory bit cells, providing, by the sensor, the temperature sense signals representing relationships between the first signals received from the group of ferroelectric memory bit cells and a respective reference voltage of the reference voltages, the reference voltages representing different temperatures.
